(19) United States
(12) Patent Application Publication
(10) Pub. No.: US 2005/0007123 A1
(43) Pub. Date: Jan. 13, 2005

(54) Method and a device for monitoring the dispersed aqueous phase of an oil-water emulsion

(76) Inventors: Wojciech Piasecki, Krakow (PL); Pal Nilsen, Bodalen (NO)

Correspondence Address: VENABLE, BAETJER, HOWARD AND CIVILETTI, LLP, P.O. BOX 34385, WASHINGTON, DC, 20043-9998, US

(21) Appl. No.: 10/485,159

(22) PCT Filed: Jul. 29, 2002
(86) PCT No.: PCT/PL02/00058

(30) Foreign Application Priority Data
Aug. 1, 2001 (PL) P-348996

(51) Int. Cl. G01R 27/04; G01R 27/32

(52) U.S. Cl. 324/637

(57) ABSTRACT

The subject of the invention is a method and a device for monitoring the parameters of the aqueous phase in water-in-oil emulsion wherein oil is in continuous phase and water is in dispersion phase in the form of droplets, applicable for the optimisation of the water-in-oil emulsion separation process. The method according to the invention consists in exposing the examined emulsion flowing through a test section of a pipe to an electromagnetic field in a microwave resonator and measuring the dielectric loss of the emulsion in one of the measuring systems and a second test section of the pipe is selected with the water-in-oil emulsion flowing through the pipe, which is exposed to an electromagnetic field of a frequency markedly lower than the microwave radiation frequency, and the dielectric loss of the emulsion is measured in the second measuring system. The results of the measurements are transmitted to a computer control device wherein the results of the measurements obtained simultaneously in both measuring systems are compared. The device according to the invention is characterised by having two resonant measuring systems /A/ and /B/ coupled with one another by means of a computer control device /C/, and one of the resonant measuring systems /A/ has an electromagnetic radiation generator /2/ of microwave frequencies, while die other resonant measuring system /B/ has an electromagnetic radiation generator /7/ of a frequency markedly lower than the microwave radiation frequency.

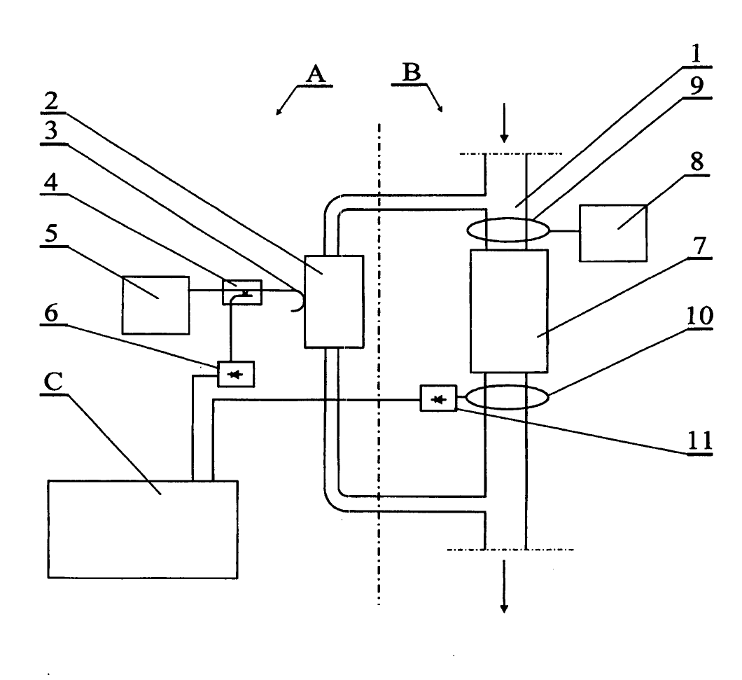

The subject of the invention is a method and a device for monitoring aqueous phase parameters in a water-in-oil emulsion, wherein oil is in a continuous phase and water is in a dispersed phase in a form of droplets, applicable for the optimisation of the water-in-oil emulsion separation process. The method and the device employ measurements of dielectric loss of a water-in-oil emulsion sample placed in the electromagnetic field.

A method of determining the water content in a water-and-oil mixture containing a relatively large amount of gas, wherein a microwave measuring device is used, is known from description U.S. Pat. No. 5,157,339. In this method a section of a pipe with water-and-oil mixture is exposed to the electromagnetic field and, at variable frequencies of the microwave field, the microwave signal decay depending on the variable frequency of the microwave generator is measured, then a statistical analysis of the results of the measurements is done and, using the variation or dispersion of the dielectric loss factor for given measuring frequencies, the quantity of gas in the water-and-oil mixture is determined. The quantity of water is determined by comparing each loss factor measured for the given frequency with the loss factor known from the measurement results recorded earlier for a mixture of a known composition.

A device for the measurement and determination of oil, water and gas content in a mixture flowing through a conveying pipe, employing electromagnetic radiation, preferably microwave radiation, and containing helical resonators arranged around a pipe with the flowing mixture, located in the device housing and provided with a suitable electromagnetic radiation detector, is known from description U.S. Pat. No. 5,398,883. By measuring the resonance frequency, which depends on the permittivity of the examined mixture in the pipe, and by measuring the resonance signal amplitude, which depends on the electromagnetic absorption of the mixture in the pipe, the complex permittivity of the mixture is determined, which serves as the basis for the determination of the individual components of the water, oil and gas mixture.

In a water-and-oil emulsion, electromagnetic radiation is absorbed mainly by the aqueous phase, as the oil phase is virtually permeable to a broad frequency range, including the microwave range. In the case of water, we can distinguish two types of absorption. The first takes place due to eddy currents induced by the magnetic constituent of an electromagnetic field, and the second is molecular absorption resulting from the interaction of water dipoles and the electric component of a high frequency electromagnetic field. The first type of absorption is strongly dependent on the specific conductance of the aqueous phase and on the size of the droplets of the dispersion phase of water in which eddy currents flow. This is the reason why this type of absorption does not occur in deionised water. The other type of absorption depends neither on specific conductance nor on the size of droplets in water dispersion phase, but it depends on the value of the imaginary part of the permittivity. A high value of this factor within the microwave frequency, and especially for the frequency range of approximately 10 GHz results in the predominance of molecular absorption. On the other hand, a frequency less than 1 GHz results in the imaginary part of the permittivity nearing zero and in such a case absorption of eddy currents prevails. The solution of the inventive method and device is based on the differences between the two types of absorption.

A method of monitoring the parameters of the aqueous phase in a water-in-oil emulsion, wherein the examined emulsion flowing through a test section of a pipe is exposed to an electromagnetic field in a microwave resonator, and the dielectric loss of the emulsion in the measuring system is measured, which system comprises a microwave radiation generator and a detector of the microwave signal permeating through the examined emulsion, consists in that another test section of the pipe with the water-in-oil emulsion flowing through it is selected and exposed to an electromagnetic field of a frequency markedly lower than the microwave radiation frequency, and the dielectric loss of the emulsion is measured in the other measuring system comprising an electromagnetic radiation source, a resonator and a detector of the electromagnetic radiation signal permeating through the examined substance, the emulsion dielectric loss measurements in both measuring systems being made at the same time and the results of the measurements being sent to a computer control device wherein the results of the measurements obtained simultaneously in the two measuring systems are compared, and then, by means of a suitable computer software installed in the computer control device the content of the aqueous phase in the examined emulsion is determined and the size of droplets occurring in this phase is determined.

Preferably, the dielectric loss of the water-in-oil emulsion in the two measuring systems is measured indirectly by measuring the quality factor of the resonators.

The essential quality of the inventive device is that it has two resonant measuring systems that are coupled by means of a computer control device, each of said systems comprises an electromagnetic radiation generator, a resonator and a measuring element in the form of a detector, and the examined water-in-oil emulsion sample is placed in the resonators, and one of the resonant measuring systems has an electromagnetic radiation generator of microwave frequencies, while the other resonant measuring system has an electromagnetic radiation generator of a frequency significantly lower than the microwave radiation frequency.

Preferably, the resonator of the second measuring system is suitable for operation within the frequency range from 10 to 100 Mz.

The advantage of the invention is that it permits the determination of two parameters characterising the aqueous phase of water-in-oil emulsion without the need to conduct troublesome measurements, especially optical measurements, which are traditionally used to determine the size of droplets in the aqueous phase.

The subject of the invention is reproduced as its embodiment in the drawing showing in the form of, a diagram a device realising the method of monitoring of the parameters of the aqueous phase in water-in-oil emulsion.

The device comprises two resonant measuring systems A and B coupled by means of a computer control device C. Both systems are placed on a test section of a pipe 1 containing the examined emulsion, in two different places of the pipe. The test section of the pipe 1, shown in the embodiment, consists of two branches through which the examined emulsion flows, and each of the two resonant measuring systems A and B is placed on a separate branch. The measuring system A contains a microwave resonator 2 placed on the branch of the test section of the pipe 1, which resonator is connected through a coupling 3 and a directional coupler 4 with a microwave generator 5. A microwave resonator 2 through the directional coupler 4 and a microwave detector 6 is connected to an input of the computer control device C whose other input is coupled with the second measuring system B. The second measuring system B contains a radio frequency resonator 7 in which the test section of the pipe 1 with the examined emulsion is placed. The resonator 7 is connected with a radio frequency resonator 8 through a coupling loop 9 and with the computer control device C through a receiving loop 10 and a detector 11.

In practice, which is not shown in the drawing, both measuring systems A and B can be placed on the same test section of the pipe not comprising any branch. However, the preferable arrangement is when the measuring system with the microwave resonator is placed on a pipe section of the decreased cross-section of the pipe.

In order to monitor the parameters of the aqueous phase in water-in-oil emulsion the stream of the examined emulsion in the test section of the pipe 1 is divided into a stream flowing through the microwave resonator 2 and a stream flowing through the radio frequency resonator 7. The resonator 2 is connected through the coupling 3 and the directional coupler 4 with the microwave generator 5. In the case when in the branch of the test section of the pipe 1 there is emulsion, a drop in the quality factor Q1 of the resonator 2, dependent on the dielectric loss of the emulsion, causes that an electromagnetic wave reflected from the resonator 2 reaches the microwave detector 6 through the directional coupler 4. The value of the power reflected by the resonator 2 in relation to the known incident power, for the geometrically established coupling 3, depends on the quality factor Q1 of the resonator 2. Consequently, the signal from the detector 6 carries information about the value of the quality factor Q1. This signal is delivered to the computer control device C. The radio frequency resonator 7 is connected with the radio frequency generator 8 through the coupling loop 9. The magnetic field of the resonator 7 induces in the receiving loop 10 a signal dependent on the value of the magnetic field induction in the resonator 7, which value depends on the quality factor Q2 of the resonator 7. The electric signal induced in the receiving loop 10 is subjected to amplitude detection by means of the detector 11. The detected signal is measured by the computer control device C. In the computer control device C an analysis of the measurements is done permitting the calculation of the quality factors Q1 and Q2 of the resonators 2 and 7, and therefore also the dielectric loss of the emulsion for the given microwave frequency and for the given radio frequency. This allows to distinguish between the dielectric loss caused by eddy currents, dependent on the size of the aqueous phase droplets, and dipole loss independent of the droplet size. The percentage content of the aqueous phase in water-in-oil emulsion is calculated by means of the computer control device C on the basis of the measured dipole loss. Knowing the percentage content of the aqueous phase and the electric conductance of this phase, the average diameter of the aqueous phase droplets is calculated by means of the control device on the basis of the measured lossiness caused by eddy currents.

In practice, the resonator 7 operates at a frequency considerably lower than 1 GHz, preferably 100 Mz, while the resonator 2 operates at a microwave frequency, preferably 10 GHz. By measuring the quality factors Q1, Q2 for each of the resonators, information is obtained about electromagnetic absorption for the two specified frequencies. Since the value Q1 of the high frequency resonator is practically independent of the size of aqueous dispersion phase droplets, but it depends only upon the quantity of water molecules, and the value Q2 of the low frequency resonator depends on the size of the aqueous dispersion phase droplets, the result of the measurements allows for the calculation of the amount of the aqueous phase as well as for the determination of the droplet size, provided that the specific conductance of the aqueous phase is known. The knowledge of these parameters allows for the optimisation of the water-in-oil emulsion separation process, and especially it permits an on-line optimisation of this process.

1. A method of monitoring of parameters of aqueous phase in water-in-oil emulsion, wherein the examined emulsion flowing through a test section of a pipe is exposed to an electromagnetic field in a microwave resonator and the dielectric loss of the emulsion is measured in a measuring system comprising a microwave radiation generator and a detector of a microwave signal permeating the examined emulsion, wherein another test section of the pipe with water-in-oil emulsion is selected and exposed to an electromagnetic field of a frequency markedly lower than the microwave radiation frequency, and the emulsion dielectric loss is measured in the second measuring system comprising an electromagnetic radiation source, a resonator and a detector of an electromagnetic radiation signal permeating through the examined emulsion, the measurements of the emulsion dielectric loss in the two measuring systems being made simultaneously, and the results of the measurements are transmitted to a computer control device, wherein the measurement results obtained simultaneously in the two measuring systems are compared, and then, by means of a suitable computer program installed in the computer control device the aqueous phase content in the examined emulsion is determined and the size of the droplets occurring in this phase is determined.

2. The method according to claim 1, wherein the dielectric loss of the water-in-oil emulsion in both measuring systems is measured indirectly by measuring the quality factor of the resonators.

3. A device for monitoring the parameters of the aqueous phase in water in-oil emulsion, comprising two resonant measuring systems coupled with one another by means of a computer control device, each of which systems comprises an electromagnetic radiation generator, a resonator and a measuring element in the form of a detector, and in the resonators there is placed the examined sample of the water-in-oil emulsion, and one of the resonant measuring systems has an electromagnetic radiation generator of microwave frequencies, while the other resonant measuring system has an electromagnetic radiation generator of a frequency markedly lower than the frequency of microwave radiation.

4. The device according to claim 3, wherein the resonator of the second measuring system is suitable for operation within the frequency range 10-100 Mz.
